(19) United States
(12) Patent Application Publication
(10) Pub. No.: US 2009/0014126 A1
(43) Pub. Date: Jan. 15, 2009

(54) SUBSTRATE PROCESSING APPARATUS AND SUBSTRATE PROCESSING METHOD

(75) Inventors: Masami Ohtani, Shimogyo-ku (JP); Yasufumi Koyama, Shimogyo-ku (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Sokudo Co., Ltd., Shimogyo-ku (JP)

(21) Appl. No.: 12/170,406

(22) Filed: Jul. 9, 2008

(30) Foreign Application Priority Data
Jul. 10, 2007 (JP) JP 2007-180697

(51) Int. Cl. H01L 21/306; H01L 21/67; B08B 3/00; B05C 11/00

(52) U.S. Cl. 156/345.24; 29/25.01; 134/56 R; 118/696

(57) ABSTRACT

A substrate processing apparatus includes a development part for performing a development process on a substrate after being subjected to exposure and a cleaning part. When the processing time in the development part is shorter than the reference time determined in advance, the development part performs all the process steps for development. On the other hand, when the processing time in the development part is longer than the reference time, the development process is split into a first half process step and a second half process step, and the development part performs a processing including the first half process step and the cleaning part performs a processing including the second half process step. Even if the development process takes a long time, it is possible to prevent deterioration in processing capability of the substrate processing apparatus on the whole by splitting the development process.

### CROSS-REFERENCES TO RELATED APPLICATIONS

This application claims priority to Japanese Patent Application 2007-180697, filed Jul. 10, 2007. The disclosure of JP 2007-180697 is hereby incorporated by reference its entirety for all purposes.

### BACKGROUND OF THE INVENTION

1. Field of the Invention

The present invention relates to a substrate processing apparatus for performing a substrate processing while sequentially transferring substrates, such as semiconductor substrates, glass substrates for liquid crystal displays, glass substrates for photomasks, substrates for optical disks and the like, to a plurality of processing parts, and more particularly to a substrate processing apparatus and a substrate processing method for performing a development process on the substrates after being subjected to an exposure process.

2. Description of the Background Art

As is well known, products such as semiconductors, liquid crystal displays and the like are manufactured by performing a series of processes including cleaning, resist coating, exposure, development, etching, formation of interlayer insulation film, thermal treatment, dicing and the like on the above-discussed substrates. Out of these processes, the development is a process for supplying a developer onto surfaces of the substrates after being subjected to the exposure process and selectively dissolving only exposed portions (or unexposed portions) of resist films to form mask patterns.

A general procedure of development is as disclosed in, for example, Japanese Patent Application Laid Open Gazette No. 10-020508 (Patent Document 1):

(1) to so supply a developer onto a stationary substrate as to make a puddle in order to progress a development reaction,

(2) to supply de-ionized water onto the substrate in order to stop the development reaction, and

(3) to rapidly rotate the substrate in order to perform spin-drying.

Further, usually, a development unit for performing the development is mounted together with a coating unit for performing resist coating and a thermal processing unit in a common substrate processing apparatus (so-called, coater & developer) in many cases, and as shown in Japanese Patent Application Laid Open Gazette No. 2006-128248 (Patent Document 2), substrates are sequentially transferred among the process units in the substrate processing apparatus to be subjected to a photolithography process before and after exposure in most cases.

Out of the various processes performed in the coater & developer, however, the development process takes a relatively long processing time, and depending on the type of resist to coat the substrates, particularly, it sometimes takes a considerably long time. In such a case, even if the processes are rapidly performed in the other process units (e.g., the coating unit), the processing capability of the apparatus on the whole depends on that of the development unit, being disadvantageously suppressed to be lower. Such a problem can be solved by simply increasing the number of development units to be mounted, but since the number of units to be mounted in one substrate processing apparatus is usually limited by hardware limitations, it is difficult to increase only the number of development units.

### SUMMARY OF THE INVENTION

The present invention is intended for a substrate processing apparatus for performing a substrate processing while sequentially transferring a substrate to a plurality of processing parts.

According to an aspect of the present invention, the substrate processing apparatus comprises a processing time judgment part for comparing a processing time required for a specific processing part out of the plurality of processing parts to perform a specific process consisting of a plurality of process steps with a reference time determined in advance, a mode selection part for selecting a split processing mode where the plurality of process steps are divided into a first half process step and a second half process step if the processing time in the specific processing part is longer than the reference time and selecting a consecutive processing mode if the processing time is shorter than the reference time, a transfer part for transferring a substrate between a second half processing part capable of performing the second half process step and the specific processing part, and a processing control part for controlling operations of the specific processing part, the second half processing part and the transfer part, and in the substrate processing apparatus, the processing control part causes the specific processing part to perform all the plurality of process steps on a substrate when the consecutive processing mode is selected, and the processing control part causes the specific processing part to perform a processing including the first half process step on a substrate and then causes the transfer part to transfer the substrate from the specific processing part to the second half processing part and causes the second half processing part to perform a processing including the second half process step on the substrate when the split processing mode is selected.

If the processing time in the specific processing part for performing the specific process consisting of a plurality of process steps is longer than the reference time determined in advance, the plurality of process steps are divided into the first half process step and the second half process step and the processing including the first half process step is performed in the specific processing part, and then the processing including the second half process step is performed in the second half processing part. Therefore, it is possible to prevent deterioration in processing capability of the substrate processing apparatus on the whole.

Preferably, the specific process is a development process on a substrate after being subjected to an exposure process.

Even if the development process takes a long time, by splitting the development process, it is possible to prevent deterioration in processing capability of the substrate processing apparatus on the whole.

The present invention is also a substrate processing apparatus for performing a development process on a substrate after being subjected to an exposure process.

According to another aspect of the present invention, the substrate processing apparatus comprises a development part for performing a development reaction progressing process for progressing a development reaction by supplying a developer onto a substrate, a development reaction stopping process for stopping the development reaction by supplying de-ionized water onto the substrate and a rough drying process, a cleaning part for performing a cleaning process and a finish drying process on the substrate after being subjected to the rough drying process, and a transfer part for transferring the substrate after being subjected to the rough drying process from the development part to the cleaning part.

Even if the development process takes a long time, by splitting the development process, it is possible to prevent deterioration in processing capability of the substrate processing apparatus on the whole. Further, the cleaning part can be provided with a cleaning function which can not be provided in the development part, to appropriately clean the substrate.

The present invention is further intended for a substrate processing method for performing a substrate processing while sequentially transferring a substrate to a plurality of processing parts.

According to a further aspect of the present invention, the substrate processing method comprises the steps of a) comparing a processing time required for a specific processing part out of the plurality of processing parts to perform a specific process consisting of a plurality of process steps with a reference time determined in advance, b) selecting a split processing mode where the plurality of process steps are divided into a first half process step and a second half process step if the processing time in the specific processing part is longer than the reference time and selecting a consecutive processing mode if the processing time is shorter than the reference time, and c) performing all the plurality of process steps on a substrate in the specific processing part when the consecutive processing mode is selected, and performing a processing including the first half process step on a substrate in the specific processing part and then transferring the substrate from the specific processing part to a second half processing part capable of performing the second half process step and performing a processing including the second half process step on the substrate in the second half processing part when the split processing mode is selected.

If the processing time in the specific processing part for performing the specific process consisting of a plurality of process steps is longer than the reference time determined in advance, the plurality of process steps are divided into the first half process step and the second half process step and the processing including the first half process step is performed in the specific processing part, and then the processing including the second half process step is performed in the second half processing part. Therefore, it is possible to prevent deterioration in processing capability of the substrate processing apparatus on the whole.

Therefore, it is an object of the present invention to prevent deterioration in processing capability of the substrate processing apparatus on the whole even if the substrate processing includes a process which takes a long time.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A and 1B are views showing the principle of the present invention;

FIG. 2 is a plan view showing a substrate processing apparatus in accordance with the present invention;

FIG. 3 is an elevational view showing a liquid processing part of the substrate processing apparatus;

FIG. 4 is an elevational view showing a thermal processing part of the substrate processing apparatus;

FIG. 5 is a view illustrating a construction of principal part of a cleaning unit;

FIG. 6 is a view illustrating a construction of principal part of a development unit;

FIG. 7 is a block diagram showing an overview of a control mechanism;

FIG. 8 is a flowchart showing a standard procedure of development process; and

FIG. 9 is a flowchart showing a procedure of development process in a case where a split processing mode is selected.

### DETAILED DESCRIPTION OF THE INVENTION

### 1. Principle of Embodiments of The Invention

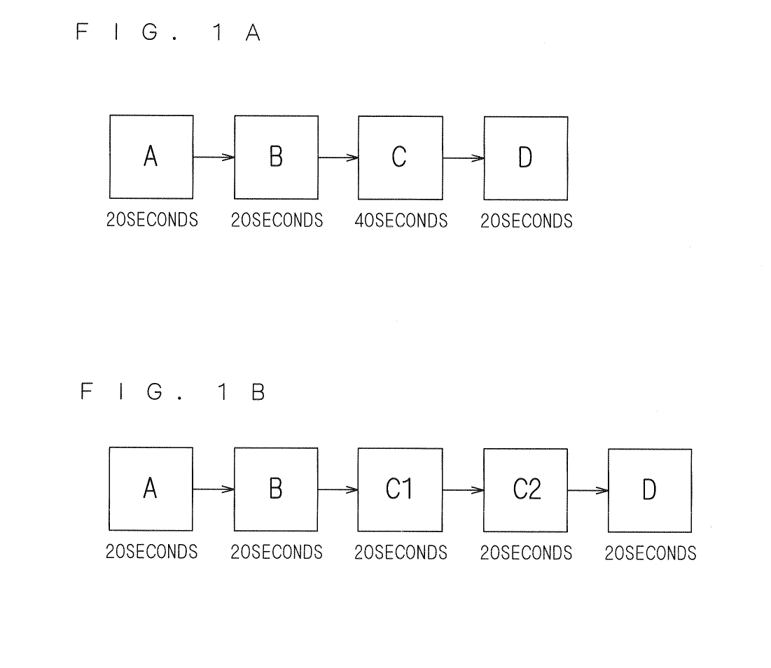

First, discussion will be made on the basic principle of embodiments of the present invention, referring to FIGS. 1A and 1B. A substrate processing apparatus is equipped with four types of processing parts for individually performing four types of processes, i.e., processes A to D, and sequentially performs the processes A to D on a plurality of substrates. The substrate processing apparatus starts performing the process A on an antecedent substrate, and after that, at the time when the process A on a following substrate stands ready to start, the substrate processing apparatus immediately starts performing the process A on the following substrate.

It is assumed, as shown in FIG. 1A, that out of the four processes, the processing time required for each of the processes A, B and D per substrate is 20 seconds and that for the process C is 40 seconds. In this case, the total processing time per substrate is 20+20+40+20=100 seconds, and since the processing time for the process C is twice that for each of the other processes, the processing time of the substrate processing apparatus on the whole depends on that of the process C. Therefore, the processing capability of this substrate processing apparatus is 3600/40=90 pieces per hour. In the case of FIG. 1A, the substrate processing apparatus can make use of only half the processing capabilities of the respective processing parts which perform the processes A, B and D, and as a result, the processing capability of the substrate processing apparatus on the whole is also lowered.

Then, as shown in FIG. 1B, the bottleneck process C which takes a longer time is split into two processes C1 and C2 and respective processing parts for performing the processes C1 and C2 are mounted in the substrate processing apparatus. It is assumed that as the result of splitting of the process C into two, the processing time for each of the processes C1 and C2 per substrate becomes 20 seconds. Though the total processing time per substrate is 20+20+20+20+20=100 seconds and equal to that in the above case of FIG. 1A, the condition where the total processing time depends on the process C is improved and the processing capability of the substrate processing apparatus on the whole is 3600/20=180 pieces per hour. In the case of FIG. 1B, it becomes possible to make full use of the processing capabilities of all the processing parts and as a result, the processing capability of the substrate processing apparatus on the whole is improved.

The above case, however, is shown very simply for easy understanding of the present invention, and actually, splitting of the process C requires some additional processes (e.g., a transfer from the processing part for the process C1 to that for the process C2 or some processes specific to the processes C1 and C2). Further, as the result of splitting of the process C, any one of the other processes A, B and D may become another bottleneck process. For these reasons, the processing capability of the substrate processing apparatus does not simply become twice when a bottleneck process is split into two processes, but it is certain that applying the process splitting technique of the present invention to a substrate processing apparatus can improve the processing capability of the apparatus on the whole to some degree. Hereinafter, detailed discussion will be made on a substrate processing apparatus to which the process splitting technique of the present invention is applied, referring to the accompanying drawings.

### 2. Overall Construction of the Substrate Processing Apparatus

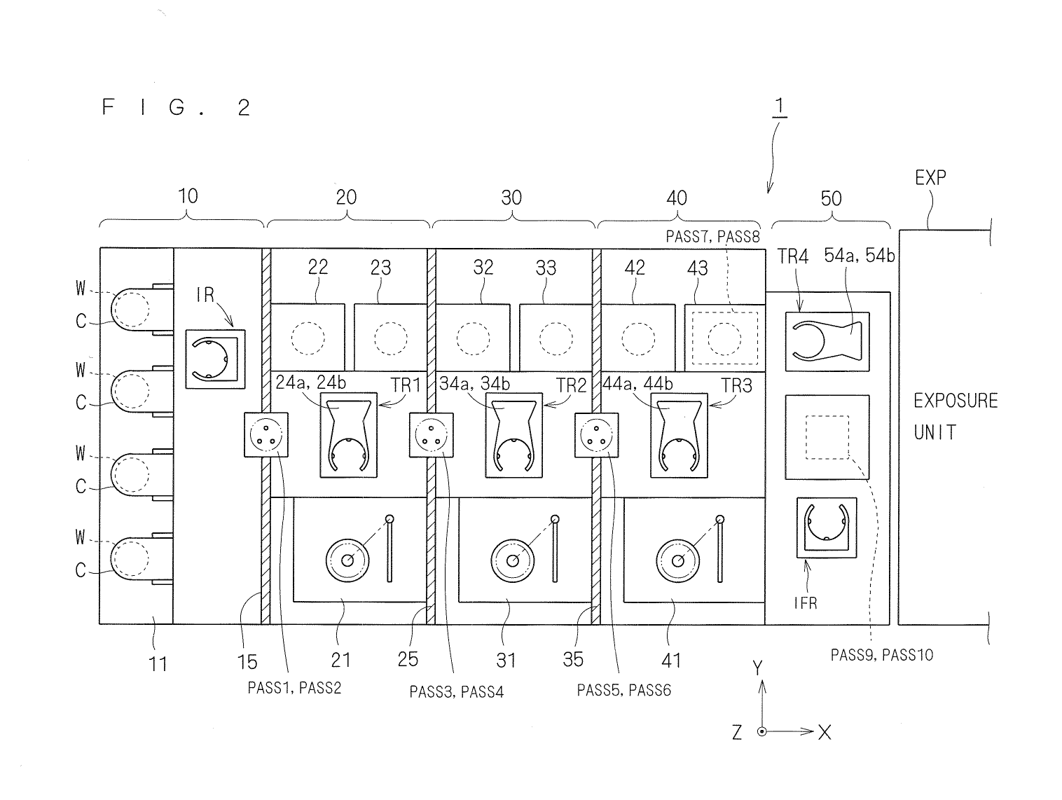

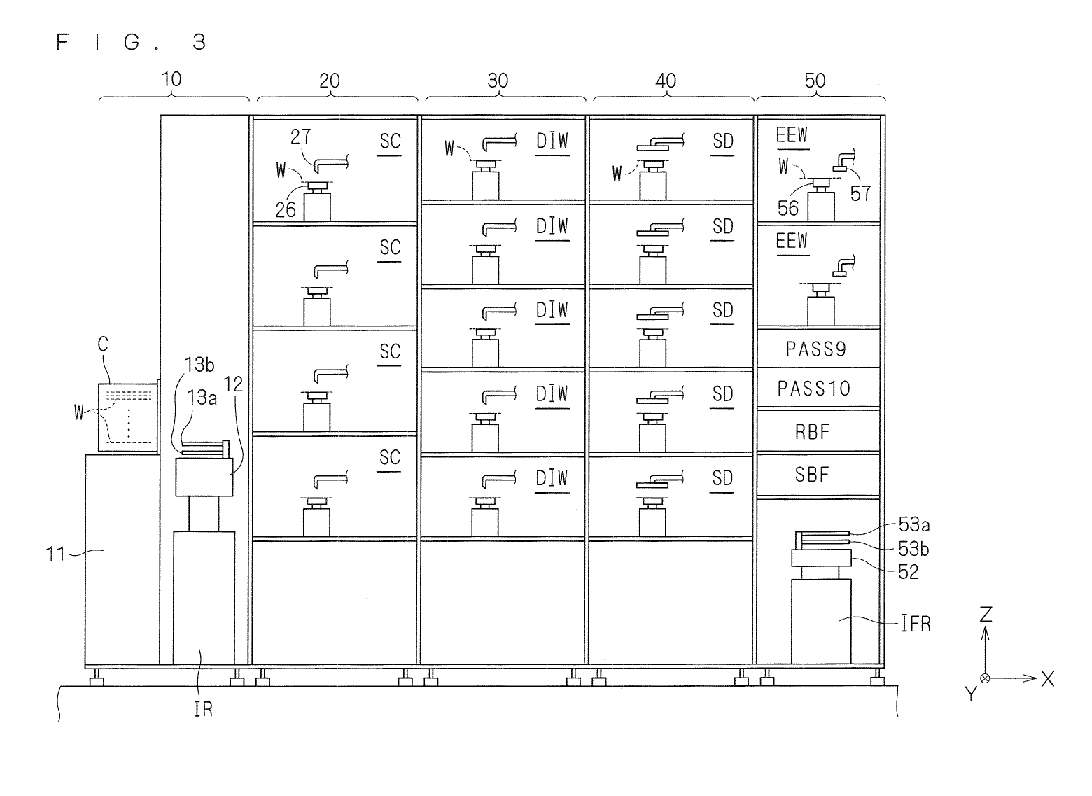

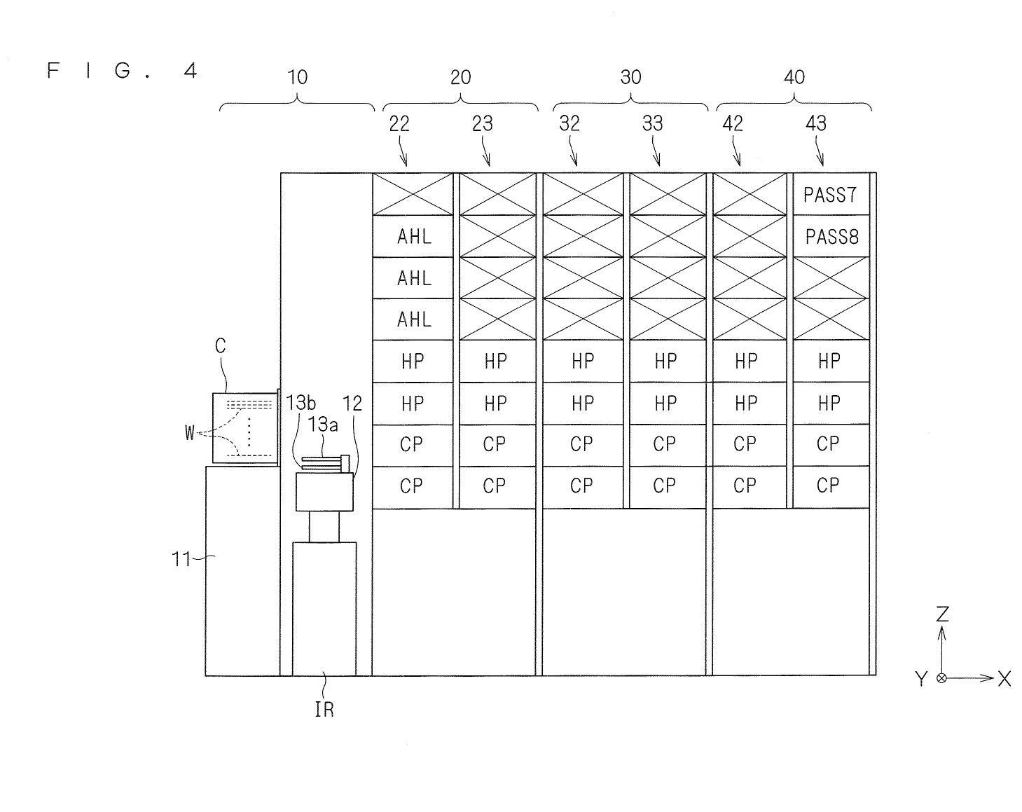

FIG. 2 is a plan view showing a substrate processing apparatus 1 in accordance with an embodiment of the present invention. FIG. 3 is an elevational view showing a liquid processing part of the substrate processing apparatus 1 and FIG. 4 is an elevational view showing a thermal processing part of the substrate processing apparatus 1. In FIG. 2 and the following figures, for clear understanding of the relation of directions, the XYZ orthogonal coordinate system with the Z-axis direction as the vertical direction and the XY plane as the horizontal plane is given as appropriate.

The substrate processing apparatus 1 of this illustrated embodiment is an apparatus which coats substrates W such as semiconductor wafers with photoresist films and performs development of the substrates W after being subjected to pattern exposure (so-called, coater & developer). The substrate W to be processed by the substrate processing apparatus 1 of the present invention is not limited to a semiconductor wafer but may be a glass substrate for liquid crystal display, a glass substrate for photomask or the like.

The substrate processing apparatus 1 of this illustrated embodiment has a construction in which five processing blocks, i.e., an indexer block 10, a resist coating block 20, a cleaning block 30, a development block 40 and an interface block 50, are arranged in parallel. The interface block 50 is connected to an exposure unit (stepper) EXP which is an external device provided separately from the substrate processing apparatus 1.

The indexer block 10 is a processing block for loading unprocessed substrates which are received from the outside of the apparatus into the apparatus and for unloading processed substrates after being subjected to development to the outside of the apparatus. The indexer block 10 comprises a rest table 11 on which a plurality of carriers C (four in this illustrated embodiment) are arranged and an indexer robot IR for taking the unprocessed substrate W out from each of the carriers C and storing the processed substrate W into each carrier C.

The indexer robot IR comprises a movable base 12 which is horizontally movable along the rest table 11 (the Y-axis direction) and vertically movable (in the Z-axis direction) and also rotatable about its shaft center along the vertical direction. The movable base 12 is equipped with two holding arms 13a and 13b for holding the substrate W in a horizontal position. The holding arms 13a and 13b are slide movable to and fro independently of each other. Therefore, each of the holding arms 13a and 13b moves horizontally along the Y-axis direction and vertically, rotates in the horizontal plane and moves to and fro along the direction of the radius of gyration. The indexer robot IR can thereby cause the holding arms 13a and 13b to individually make access to each carrier C to take the unprocessed substrate W out from and store the processed substrate W into it. As the carrier C, an FOUP (Front Opening Unified Pod) for housing the substrates W in a sealed space, an SMIF (Standard Mechanical InterFace) pod or an OC (Open Cassette) in which the housed substrates W are exposed to outside air may be used.

The resist coating block 20 is provided adjacently to the indexer block 10. Between the indexer block 10 and the resist coating block 20 provided is a partition 15 for interrupting an atmosphere. The partition 15 is equipped with two vertically-layered substrate rest parts PASS1 and PASS2 on which the substrates W are rested to be transferred between the indexer block 10 and the resist coating block 20.

The upper substrate rest part PASS1 is used to transfer the substrates W from the indexer block 10 to the resist coating block 20. The substrate rest part PASS1 comprises three support pins, and the indexer robot IR of the indexer block 10 puts the unprocessed substrate W taken out from the carrier C onto the three support pins of the substrate rest part PASS1. Then, a transfer robot TR1 of the resist coating block 20 discussed later receives the substrate W rested on the substrate rest part PASS 1. On the other hand, the lower substrate rest part PASS2 is used to transfer the substrates W from the resist coating block 20 to the indexer block 10. The substrate rest part PASS2 also comprises three support pins, and the transfer robot TR1 of the resist coating block 20 puts the processed substrate W onto the three support pins of the substrate rest part PASS2. After that, the indexer robot IR receives the substrate W rested on the substrate rest part PASS2 and stores it into the carrier C. Further, substrate rest parts PASS3 and PASS 10 each have the same structure as that of the substrate rest parts PASS1 and PASS2.

The substrate rest parts PASS1 and PASS2 extend through part of the partition 15. The substrate rest parts PASS 1 and PASS2 are each equipped with an optical sensor (not shown) for detecting whether there is a substrate W or not, and it is judged, on the basis of a detection signal of each sensor, whether the indexer robot IR and the transfer robot TR1 stand ready to pass or receive the substrate W to/from the substrate rest part PASS1 or PASS2 or not.

Next, discussion will be made on the resist coating block 20. The resist coating block 20 is a processing block for coating the substrate W with a photoresist to form a resist film. In this embodiment, as the photoresist, a chemically amplified resist is used. The resist coating block 20 comprises a resist coating part 21 for applying a resist, resist film formation thermal processing parts 22 and 23 for performing various thermal processings accompanying a resist coating process and a transfer robot TR1 for passing and receiving the substrate W to/from the resist coating part 21 and the resist film formation thermal processing parts 22 and 23.

In the resist coating block 20, the resist coating part 21 and the resist film formation thermal processing parts 22 and 23 are opposed to each other with the transfer robot TR1 interposed therebetween. Specifically, the resist coating part 21 is disposed on the front side of the apparatus (the (−Y) side) and the two resist film formation thermal processing parts 22 and 23 are disposed on the rear side (the (+Y) side). Further, on the front side of the resist film formation thermal processing parts 22 and 23, a not-shown thermal barrier is provided. Arranging the resist coating part 21 and the resist film formation thermal processing parts 22 and 23 apart from each other and providing the thermal barrier therebetween avoid the thermal effect of the resist film formation thermal processing parts 22 and 23 upon the resist coating part 21.

As shown in FIG. 3, the resist coating part 21 has a construction in which four coating units SC having the same construction are vertically layered. Each of the four coating units SC comprises a spin chuck 26 for rotating the substrate W in a substantially horizontal plane while holding the substrate W in a substantially horizontal position by adsorption, a coating nozzle 27 for discharging a coating solution for resist film onto the substrate W held on the spin chuck 26, a spin motor (not shown) for rotatably driving the spin chuck 26, a cup (not shown) surrounding the substrate W held on the spin chuck 26, and the like.

As shown in FIG. 4, in the resist film formation thermal processing part 22, two heating units HP for heating the substrate W up to a predetermined temperature, two cooling units CP for cooling the heated substrate W down to another predetermined temperature and keeping the substrate W at the temperature and three adhesion promotion units AHL for performing a thermal processing on the substrate W in a vapor atmosphere of HMDS (hexamethyldisilazane) to promote adhesion between the resist film and the substrate W are vertically layered. On the other hand, also in the resist film formation thermal processing part 23, two heating units HP and two cooling units CP are vertically layered. The areas indicated by the cross marks (X) in FIG. 3 are each occupied by a piping and wiring section or reserved as empty space (the same applies to other thermal processing parts discussed later).

The transfer robot TR1 comprises two transfer arms 24a and 24b for holding the substrate W in a substantially horizontal position, which are vertically arranged closely to each other. Each of the transfer arms 24a and 24b has a tip portion of “C” shape in a plan view, and a plurality of pins projected inward from the inside of this C-shaped arm support the peripheral edge of the substrate W from underneath. Further, the transfer robot TR1 can vertically move the two transfer arms 24a and 24b (in the Z direction) and rotate them about its shaft center along the vertical direction. The transfer robot TR1 can also move the two transfer arms 24a and 24b to and fro in the horizontal direction (the direction of the radius of gyration) independently of each other. Therefore, the transfer robot TR1 can cause the two transfer arms 24a and 24b to individually make access to the substrate rest parts PASS1 and PASS2, the thermal processing units (the heating units HP, the cooling units CP and the adhesion promotion units AHL) provided in the resist film formation thermal processing parts 22 and 23, the coating units SC provided in the resist coating part 21 and substrate rest parts PASS3 and PASS4 described later to pass and receive the substrates W to/from these units.

Next, discussion will be made on the cleaning block 30. The cleaning block 30 is so disposed as to be sandwiched between the resist coating block 20 and the development block 40. Also between the cleaning block 30 and the resist coating block 20 provided is the partition 25 for interrupting an atmosphere. Extending through part of this partition 25, two substrate rest parts PASS3 and PASS4 on which the substrates W are rested to be passed between the resist coating block 20 and the cleaning block 30 are vertically layered. The substrate rest parts PASS3 and PASS4 each have the same structure as that of the above-discussed substrate rest parts PASS1 and PASS2.

The upper substrate rest part PASS3 is used to transfer the substrates W from the resist coating block 20 to the cleaning block 30. Specifically, a transfer robot TR2 of the cleaning block 30 receives the substrate W which is put onto the substrate rest part PASS3 by the transfer robot TR1 of the resist coating block 20. On the other hand, the lower substrate rest part PASS4 is used to transfer the substrates W from the cleaning block 30 to the resist coating block 20. Specifically, the transfer robot TR1 of the resist coating block 20 receives the substrate W which is put onto the substrate rest part PASS4 by the transfer robot TR2 of the cleaning block 30.

The substrate rest parts PASS3 and PASS4 extend through part of the partition 25. The substrate rest parts PASS3 and PASS4 are each equipped with an optical sensor (not shown) for detecting whether there is a substrate W or not, and it is judged, on the basis of a detection signal of each sensor, whether the transfer robots TR1 and TR2 stand ready to pass or receive the substrate W to/from substrate rest part PASS3 or PASS4 or not.

The cleaning block 30 is a processing block for cleaning the substrate W after being subjected to the development reaction progressing process in the development block 40. The cleaning block 30 comprises a cleaning part 31 for supplying de-ionized water onto the substrate W to clean it, two post-development thermal processing parts 32 and 33 for performing a thermal processing after the development process, the transfer robot TR2 for passing and receiving the substrate W to/from the cleaning part 31 and the post-development thermal processing parts 32 and 33.

In the cleaning block 30, the cleaning part 31 and the post-development thermal processing parts 32 and 33 are opposed to each other with the transfer robot TR2 interposed therebetween. Specifically, the cleaning part 31 is disposed on the front side of the apparatus and the two post-development thermal processing parts 32 and 33 are disposed on the rear side. Further, on the front side of the post-development thermal processing parts 32 and 33, a not-shown thermal barrier is provided. Arranging the cleaning part 31 and the post-development thermal processing parts 32 and 33 apart from each other and providing the thermal barrier therebetween avoid the thermal effect of the post-development thermal processing parts 32 and 33 upon the cleaning part 31.

As shown in FIG. 3, the cleaning part 31 has a construction in which five cleaning units DIW having the same construction are vertically layered. The construction of each of the cleaning units DIW will be discussed later in detail.

As shown in FIG. 4, in the post-development thermal processing part 32, two heating units HP for heating the substrate W up to a predetermined temperature and two cooling units CP for cooling the heated substrate W down to another predetermined temperature and keeping the substrate W at the temperature are vertically layered. On the other hand, also in the post-development thermal processing part 33, two heating units HP and two cooling units CP are vertically layered.

The transfer robot TR2 comprises two transfer arms 34a and 34b for holding the substrate W in a substantially horizontal position, which are vertically arranged closely to each other. Their construction and operation mechanism are the same as those of the transfer robot TR1. Therefore, the transfer robot TR2 can cause the two transfer arms 34a and 34b to individually make access to the substrate rest parts PASS3 and PASS4, the thermal processing units provided in the post-development thermal processing parts 32 and 33, the cleaning units DIW provided in the cleaning part 31 and substrate rest parts PASS5 and PASS6 described later to pass and receive the substrates W to/from these units.

Next, discussion will be made on the development block 40. The development block 40 is so disposed as to be sandwiched between the cleaning block 30 and the interface block 50. Also between the development block 40 and the cleaning block 30 provided is the partition 35 for interrupting an atmosphere. Extending through part of this partition 35, two substrate rest parts PASS5 and PASS6 on which the substrates W are rested to be passed between the cleaning block 30 and the development block 40 are vertically layered. The substrate rest parts PASS5 and PASS6 each have the same structure as that of the above-discussed substrate rest parts PASS1 and PASS2.

The upper substrate rest part PASS5 is used to transfer the substrates W from the cleaning block 30 to the development block 40. Specifically, a transfer robot TR3 of the development block 40 receives the substrate W which is put onto the substrate rest part PASS5 by the transfer robot TR2 of the cleaning block 30. On the other hand, the lower substrate rest part PASS6 is used to transfer the substrates W from the development block 40 to the cleaning block 30. Specifically, the transfer robot TR2 of the cleaning block 30 receives the substrate W which is put onto the substrate rest part PASS6 by the transfer robot TR3 of the development block 40.

The substrate rest parts PASS5 and PASS6 extend through part of the partition 35. The substrate rest parts PASS5 and PASS6 are each equipped with an optical sensor (not shown) for detecting whether there is a substrate W or not, and it is judged, on the basis of a detection signal of each sensor, whether the transfer robots TR2 and TR3 stand ready to pass or receive the substrate W to/from substrate rest part PASS5 or PASS6 or not.

The development block 40 is a processing block for performing development on the substrate W after being subjected to exposure. The development block 40 comprises a development part 41 for supplying a developer onto the substrate W on which a pattern is exposed to perform development, a post-development thermal processing part 42 for performing a thermal processing after the development process, a post-exposure baking part 43 for performing a thermal processing on the substrate W immediately after exposure and the transfer robot TR3 for passing and receiving the substrate W to/from the development part 41 and the post-development thermal processing part 42.

As shown in FIG. 3, the development part 41 has a construction in which five development units SD having the same construction are vertically layered. The construction of each of the development units SD will be discussed later in detail.

As shown in FIG. 4, in the post-development thermal processing part 42, two heating units HP for heating the substrate W up to a predetermined temperature and two cooling units CP for cooling the heated substrate W down to another predetermined temperature and keeping the substrate W at the temperature are vertically layered. On the other hand, also in the post-exposure baking part 43, two heating units HP and two cooling units CP are vertically layered. The heating units HP of the post-exposure baking part 43 each perform a PEB (Post Exposure Bake) on the substrate W immediately after exposure. To/from the heating units HP and the cooling units CP of the post-exposure baking part 43, a transfer robot TR4 of the interface block 50 loads and unloads the substrates W.

Further, in the post-exposure baking part 43, two substrate rest parts PASS7 and PASS8 for passing and receiving the substrate W to/from the development block 40 and the interface block 50 are integrated, being vertically layered closely to each other. The upper substrate rest part PASS7 is used to transfer the substrates W from the development block 40 to the interface block 50. Specifically, the transfer robot TR4 of the interface block 50 receives the substrate W which is put onto the substrate rest part PASS7 by the transfer robot TR3 of the development block 40. On the other hand, the lower substrate rest part PASS8 is used to transfer the substrates W from the interface block 50 to the development block 40. Specifically, the transfer robot TR3 of the development block 40 receives the substrate W which is put onto the substrate rest part PASS8 by the transfer robot TR4 of the interface block 50. The substrate rest parts PASS7 and PASS8 are open both to the transfer robot TR3 of the development block 40 and to the transfer robot TR4 of the interface block 50.

The transfer robot TR3 comprises two transfer arms 44a and 44b for holding the substrate W in a substantially horizontal position, which are vertically arranged closely to each other. Their construction and operation mechanism are the same as those of the transfer robot TR1. Therefore, the transfer robot TR3 can cause the two transfer arms 44a and 44b to individually make access to the substrate rest parts PASS5 and PASS6, the thermal processing units provided in the post-development thermal processing part 42, the development units SD provided in the development part 41 and substrate rest parts PASS7 and PASS8 of the post-exposure baking part 43 to pass and receive the substrates W to/from these units.

Next, discussion will be made on the interface block 50. The interface block 50 is a processing block which is disposed adjacently to the development block 40, to pass an unexposed substrate W coated with a resist film to an exposure unit EXP which is an external device provided separately from the substrate processing apparatus 1 and to receive an exposed substrate W from the exposure unit EXP and pass it to the development block 40. The interface block 50 comprises an transfer mechanism IFR for passing and receiving the substrate W to/from the exposure unit EXP, two edge exposure units EEW for exposing the peripheral portion of the substrate W on which a resist film is formed and the transfer robot TR4 for passing and receiving the substrate W to/from the post-exposure baking part 43 of the development block 40 and the edge exposure unit EEW.

As shown in FIG. 3, each of the two edge exposure units EEW comprises a spin chuck 56 for rotating the substrate W in a substantially horizontal plane while holding the substrate W in a substantially horizontal position by adsorption and a photoirradiator 57 for irradiating the peripheral edge of the substrate W held on the spin chuck 56 with light to expose it. The two edge exposure units EEW are vertically layered at the center of the interface block 50. Below the edge exposure units EEW, two substrate rest parts PASS9 and PASS 10, a return buffer RBF for returning the substrate W and a send buffer SBF for sending the substrate W are vertically layered. The upper substrate rest part PASS9 is used to pass the substrates W from the transfer robot TR4 to the transfer mechanism IFR, and the lower substrate rest part PASS10 is used to pass the substrates W from the transfer mechanism IFR to the transfer robot TR4.

The return buffer RBF temporally stores the substrate W after being subjected to the PEB (Post Exposure Bake) by the post-exposure baking part 43 of the development block 40 when the development block 40 can not perform development on the exposed substrate W due to some trouble. On the other hand, the send buffer SBF temporally stores the substrate W before exposure when the exposure unit EXP can not receive the unexposed substrate W. The return buffer RBF and the send buffer SBF are each a storage rack having multiple stages for storing a plurality of substrates W. The transfer robot TR4 makes access to the return buffer RBF and the transfer mechanism IFR makes access to the send buffer SBF.

The transfer robot TR4 disposed adjacently to the post-exposure baking part 43 of the development block 40 comprises two transfer arms 54a and 54b for holding the substrate W in a substantially horizontal position, which are vertically arranged closely to each other, and their construction and operation mechanism are the same as those of the transfer robot TR1. The transfer mechanism IFR comprises a movable base 52 which is horizontally movable along the Y-axis direction and vertically movable and also rotatable about its shaft center along the vertical direction, and the movable base 52 is equipped with two holding arms 53a and 53b for holding the substrate W in a horizontal position. The holding arms 53a and 53b are slide movable to and fro independently of each other. Therefore, each of the holding arms 53a and 53b moves horizontally along the Y-axis direction and vertically, rotates in the horizontal plane and moves to and fro along the direction of the radius of gyration.

<2-1. Construction of the Cleaning Unit>

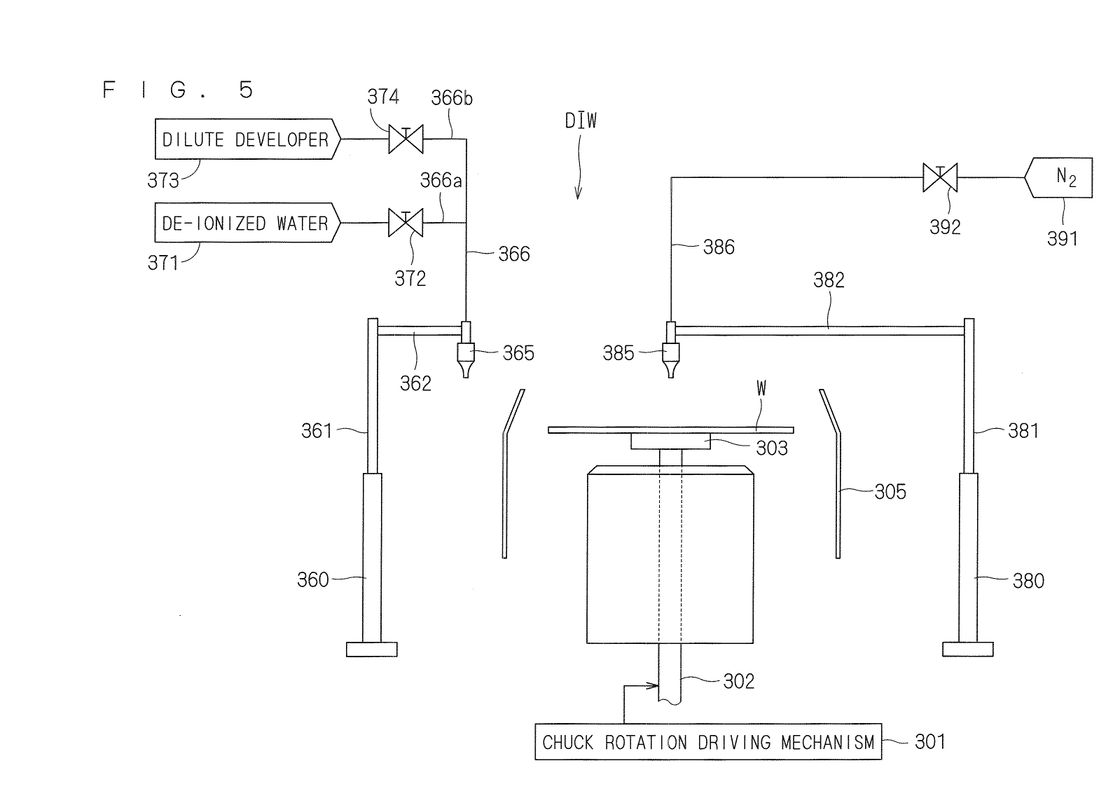

Next, discussion will be made on a construction of the cleaning unit DIW provided in the cleaning part 31. FIG. 5 is a view illustrating a construction of principal part of the cleaning unit DIW. The cleaning unit DIW comprises a spin chuck 303 for rotating the substrate W about a vertical rotation shaft through the center of the substrate W while holding the substrate W in a horizontal position.

The spin chuck 303 is fixed onto an upper end of a rotation shaft 302 rotated by a chuck rotation driving mechanism 301 including a spin motor and the like. The spin chuck 303 is provided with an intake path (not shown), and air inside the intake path is exhausted while the substrate W is rested on the spin chuck 303, to vacuum-adsorb a lower surface of the substrate W to the spin chuck 303. This allows the substrate W to be held in a horizontal position.

On one side of a cup 305 surrounding the substrate W held on the spin chuck 303 provided is a rotation motor 360. To the rotation motor 360 connected is a rotation shaft 361. An arm 362 is so connected to the rotation shaft 361 as to extend in the horizontal direction and the tip of the arm 362 is provided with a rinse nozzle 365. The rotation motor 360 drives rotation of the rotation shaft 361 to rotate the arm 362, and the rinse nozzle 365 is thereby moved between a position above the substrate W held on the spin chuck 303 and another position outside the cup 305.

With the rinse nozzle 365 communicated is the tip of a rinse solution supply tube 366. The base end side of the rinse solution supply tube 366 branches off into two ends, and one branching tube 366a is connected to a de-ionized water source 371 and the other branching tube 366b is connected to a dilute developer source 373. A valve 372 is inserted in the branching tube 366a and a valve 374 is inserted in the branching tube 366b. By controlling the opening and closing of the valves 372 and 374, it is possible to select the solution to be supplied onto the upper surface of the substrate W through the rinse solution supply tube 366 and control the amount of solution to be supplied. Specifically, by opening the valve 372, de-ionized water is supplied onto the substrate W from the rinse nozzle 365, and by opening the valve 374, a dilute developer is supplied onto the substrate W.

On the other hand, the other side of the cup 305 provided is a rotation motor 380. To the rotation motor 380 connected is a rotation shaft 381. An arm 382 is so connected to the rotation shaft 381 as to extend in the horizontal direction and the tip of the arm 382 is provided with a drying nozzle 385. The rotation motor 380 drives rotation of the rotation shaft 381 to rotate the arm 382, and the drying nozzle 385 is thereby moved between a position above the substrate W held on the spin chuck 303 and another position outside the cup 305.

With the drying nozzle 385 communicated is the tip of a drying gas supply tube 386. The drying gas supply tube 386 is communicated with a nitrogen gas source 391 through a valve 392. By controlling the opening and closing of the valve 392, it is possible to control the amount of nitrogen gas (N2) to be supplied to the drying gas supply tube 386. The nitrogen gas supplied from the nitrogen gas source 391 is sent to the drying nozzle 385 through the drying gas supply tube 386. The nitrogen gas can be thereby supplied from the drying nozzle 385 to the upper surface of the substrate W. Further, instead of the nitrogen gas, other inert gases (e.g., argon gas (Ar)) may be used as the drying gas.

In order to supply the de-ionized water or the dilute developer onto the upper surface of the substrate W, the rinse nozzle 365 is positioned above the substrate W held on the spin chuck 303 and the drying nozzle 385 escapes to a predetermined position. Conversely, in order to supply the nitrogen gas onto the upper surface of the substrate W, the drying nozzle 385 is positioned above the substrate W held on the spin chuck 303 and the rinse nozzle 365 escapes to a predetermined position.

<2-2. Construction of the Development Unit>

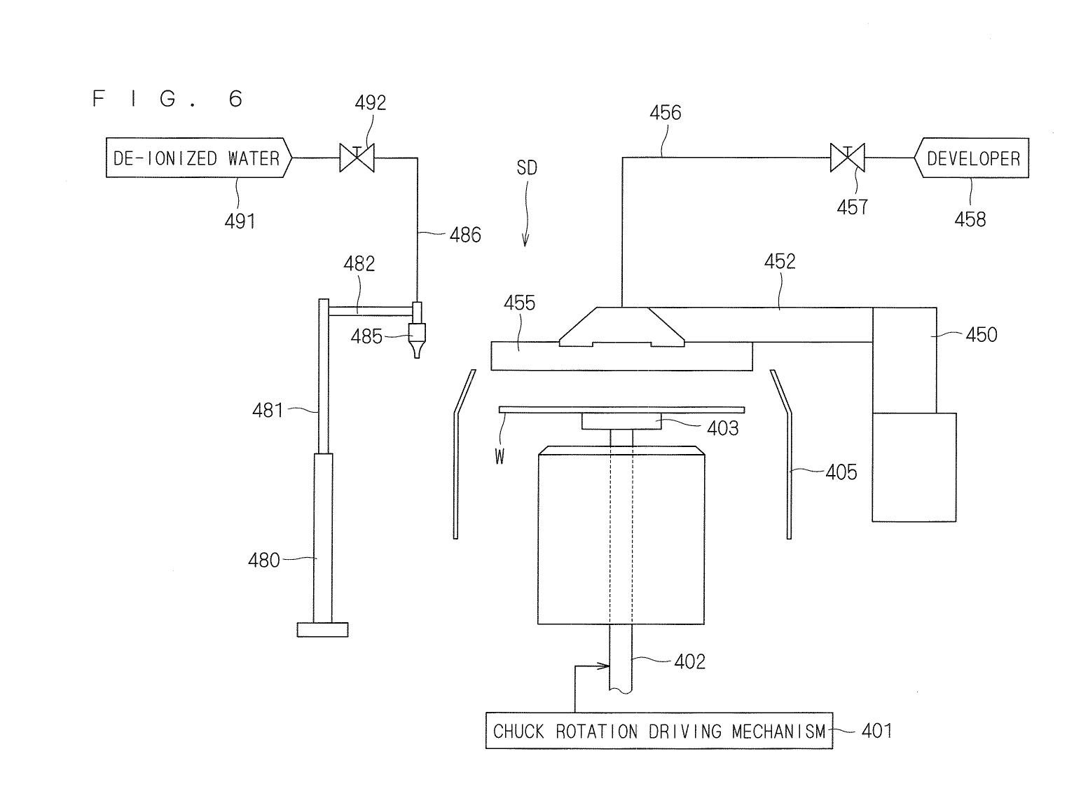

Next, discussion will be made on a construction of the development unit SD provided in the development part 41. FIG. 6 is a view illustrating a construction of principal part of the development unit SD. The development unit SD comprises a spin chuck 403 for rotating the substrate W about a vertical rotation shaft through the center of the substrate W while holding the substrate W in a horizontal position.

The spin chuck 403 is fixed onto an upper end of a rotation shaft 402 rotated by a chuck rotation driving mechanism 401 including a spin motor and the like. The spin chuck 403 is provided with an intake path (not shown), and air inside the intake path is exhausted while the substrate W is rested on the spin chuck 403, to vacuum-adsorb a lower surface of the substrate W to the spin chuck 403. This allows the substrate W to be held in a horizontal position.

Above the spin chuck 403 provided is a slit nozzle 455. A slit-like discharge port having a length not shorter than the diameter of the substrate W is formed at a lower end surface of the slit nozzle 455. Further, the slit nozzle 455 is equipped with an arm 452 which is so supported by a slide driving part 450 as to be horizontally movable. The slide driving part 450 drives the slit nozzle 455 to slidingly move immediately above the substrate W held on the spin chuck 403 in parallel with the substrate W.

With the slit nozzle 455 communicated is the tip of a developer supply tube 456. The base end side of the developer supply tube 456 is connected to a developer source 458. A valve 457 is inserted in the developer supply tube 456, and by controlling the opening and closing of the valve 457, it is possible to control the amount of developer to be supplied onto the substrate W from the developer source 458 through the slit nozzle 455.

On the other hand, on a side of a cup 405 surrounding the substrate W held on the spin chuck 403 provided is a rotation motor 480. To the rotation motor 480 connected is a rotation shaft 481. An arm 482 is so connected to the rotation shaft 481 as to extend in the horizontal direction and the tip of the arm 482 is provided with a rinse nozzle 485. The rotation motor 480 drives rotation of the rotation shaft 481 to rotate the arm 482, and the rinse nozzle 485 is thereby moved between a position above the substrate W held on the spin chuck 403 and another position outside the cup 405.

With the rinse nozzle 485 communicated is the tip of a rinse solution supply tube 486. The base end side of the rinse solution supply tube 486 is connected to a de-ionized water source 491. A valve 492 is inserted in the rinse solution supply tube 486, and by controlling the opening and closing of the valve 492, it is possible to control the amount of de-ionized water to be supplied onto the substrate W from the de-ionized water source 491 through the rinse solution supply tube 486.

<2-3. Control Mechanism of the Substrate Processing Apparatus>

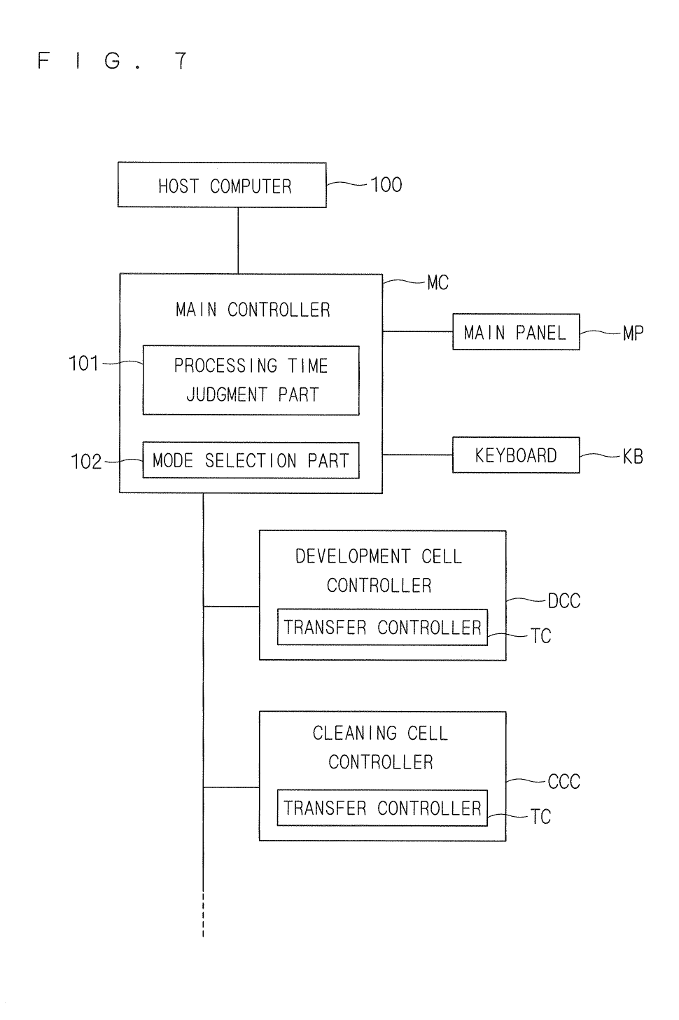

Next, discussion will be made on a control mechanism of the substrate processing apparatus. FIG. 7 is a block diagram showing an overview of the control mechanism. The substrate processing apparatus 1 comprises a control mechanism having a hierarchical structure, and the control mechanism comprises a higher-level main controller MC and a plurality of lower-level cell controllers as shown in FIG. 7. The cell controller refers to a control part for controlling a cell consisting of one transfer robot (including an indexer robot IR and a transfer mechanism IFR) and a processing part which is a transfer target of the transfer robot. The substrate processing apparatus 1 of an embodiment includes six cell controllers. In FIG. 7, out of the six cell controllers, only a development cell controller DCC and a cleaning cell controller CCC are shown. The main controller MC and the cell controllers each have a hardware construction of general computer. Specifically, each controller comprises a CPU for performing various computations, a ROM for storing a basic program, a RAM which is a readable and writable memory for storing various information and a magnetic disk or the like for storing control applications or data.

As the higher-level main controller MC, one controller is provided in the substrate processing apparatus 1 on the whole and mainly controls the whole apparatus, a main panel MP and the cell controllers. The main panel MP functions as a display of the main controller MC. To the main controller MC, various commands can be inputted from a keyboard KB. Further, the input operation may be performed from a main panel MP formed of a touch panel to the main controller MC.

A processing time judgment part 101 and a mode selection part 102 are function processing parts implemented by the CPU of the main controller MC executing a predetermined application. The details of the processings in the processing time judgment part 101 and the mode selection part 102 will be further discussed later.

The development cell controller DCC is a controller for controlling a development cell consisting of the development part 41, the post-development thermal processing part 42 and the transfer robot TR3. A transfer controller TC implemented in the development cell controller DCC controls an operation of the transfer robot TR3. The development cell controller DCC controls operations of the process units in the development part 41 and the post-development thermal processing part 42 through unit controllers which are lower control parts.

The cleaning cell controller CCC is a controller for controlling a cleaning cell consisting of the cleaning part 31, the post-development thermal processing parts 32 and 33 and the transfer robot TR2. A transfer controller TC implemented in the cleaning cell controller CCC controls an operation of the transfer robot TR2. The cleaning cell controller CCC controls operations of the process units in the cleaning part 31 and the post-development thermal processing parts 32 and 33 through unit controllers which are lower control parts.

As a control mechanism still higher than the main controller MC, a host computer 100 connected to the substrate processing apparatus 1 via a LAN line serves. The host computer 100 comprises a CPU for performing various computations, a ROM for storing a basic program, a RAM which is a readable and writable memory for storing various information and a magnetic disk or the like for storing control applications or data and has a construction of general computer. To the host computer 100, usually, a plurality of substrate processing apparatuses 1 of this embodiment are connected. The host computer 100 passes a recipe describing a procedure and processing conditions to each of the substrate processing apparatuses 1 connected thereto. The recipe received from the host computer 100 is stored in a storage part (e.g., a memory) of the main controller MC of each substrate processing apparatus 1.

The exposure unit EXP is provided with another control part independently of the above control mechanism of the substrate processing apparatus 1. Specifically, the exposure unit EXP does not operate under control of the main controller MC of the substrate processing apparatus 1 but controls its own operation by itself. The exposure unit EXP, however, also receives a recipe from the host computer 100 and controls its own operation in accordance with the recipe, and the substrate processing apparatus 1 performs an operation in synchronization with the exposure process in the exposure unit EXP.

### 3. Operation of the Substrate Processing Apparatus

Next, discussion will be made on an operation of the substrate processing apparatus 1 of a specific embodiment. Hereinafter, first, a general procedure in the substrate processing apparatus 1 will be briefly discussed. In order to execute the procedure discussed below, the control mechanism of FIG. 7 controls the constituent parts in accordance with the detail of the recipe received from the host computer 100.

First, an unprocessed substrate W held in the carrier C is transferred by an AGV (Automated Guided Vehicle) or the like from the outside of the apparatus into the indexer block 10. Subsequently, the unprocessed substrate W is taken out from the indexer block 10. Specifically, the indexer robot IR takes the unprocessed substrate W out from a predetermined carrier C and puts it onto the upper substrate rest part PASS1. When the unprocessed substrate W is rested on the substrate rest part PASS 1, the transfer robot TR1 of the resist coating block 20 uses one of the transfer arms 24a and 24b to receive the substrate W. Then, the transfer robot TR1 transfers the unprocessed substrate W which is thus received to any one of the adhesion promotion units AHL in the resist film formation thermal processing part 22. In the adhesion promotion unit AHL, the substrate W is subjected to the thermal processing in a vapor atmosphere of HMDS, to promote the adhesion between a resist film and the substrate W. The substrate W after being subjected to an adhesion promotion process is taken out by the transfer robot TR1 and transferred to any one of the cooling units CP in the resist film formation thermal processing parts 22 and 23, where being cooled.

Subsequently, the cooled substrate W is transferred by the transfer robot TR1 from the cooling unit CP to any one of the coating units SC in the resist coating part 21. In the coating unit SC, a coating solution for photoresist is applied to the surface of the substrate W, to perform spin coating. In this specific embodiment, a chemically amplified resist is applied onto the substrate W.

After the resist coating process, the substrate W is transferred by the transfer robot TR1 from the coating unit SC to any one of the heating units HP in the resist film formation thermal processing parts 22 and 23. In the heating unit HP, the substrate W is subjected to a PAB (Post Applied Bake), to form a resist film thereon with solvent ingredients in the resist removed. After that, the substrate W taken out from the heating unit HP is transferred by the transfer robot TR1 to any one of the cooling units CP in the resist film formation thermal processing parts 22 and 23, where being cooled. The cooled substrate W is put onto the substrate rest part PASS3 by the transfer robot TR1.

Next, when the substrate W with the resist film formed thereon is rested on the substrate rest part PASS3, the transfer robot TR2 of the cleaning block 30 receives the substrate W and puts it onto the substrate rest part PASS5. Further, the substrate W rested on the substrate rest part PASS5 is taken therefrom and put onto the substrate rest part PASS7 by the transfer robot TR3 of the development block 40. Then, the substrate W rested on the substrate rest part PASS7 is taken by the transfer robot TR4 of the interface block 50 and loaded into either of the upper and lower edge exposure units EEW. In the edge exposure unit EEW, the edge portion of the substrate W is subjected to the exposure process (edge exposure process). The substrate W after being subjected to the edge exposure process is put onto the substrate rest part PASS9 by the transfer robot TR4. Then, the substrate W rested on the substrate rest part PASS9 is received by the transfer mechanism IFR and loaded into the exposure unit EXP, where being subjected to a pattern exposure process. Since the chemically amplified resist is used in this embodiment, an acid is generated by the photochemical reaction in an exposed portion of the resist film formed on the substrate W.

The exposed substrate W after being subjected to the pattern exposure process is returned to the interface block 50 from the exposure unit EXP and put onto the substrate rest part PASS10 by the transfer mechanism IFR. When the exposed substrate W is rested on the substrate rest part PASS10, the transfer robot TR4 received the substrate W and transfers it to any one of the heating units HP in the post-exposure baking part 43 of the development block 40. The heating unit HP in the post-exposure baking part 43 progresses reactions such as crosslinking, polymerization and the like of a resin of the resist, using a product generated by the photochemical reaction in exposure as an acid catalyst, to perform the PEB (Post Exposure Bake) in order to locally change the solubility of only the exposed portion in the developer.

A mechanism inside the heating unit HP cools the substrate W after being subjected to the PEB, to stop the above chemical reaction. Subsequently, the substrate W is taken out from the heating unit HP of the post-exposure baking part 43 by the transfer robot TR4 and put onto the substrate rest part PASS8.

The substrate W rested on the substrate rest part PASS8 is subjected to the development process by only the development block 40 or by both the development block 40 and the cleaning block 30, and this process will be discussed later. In either case, the substrate W after being subjected to the development process is put onto the substrate rest part PASS4 by the transfer robot TR2 of the cleaning block 30. The substrate W rested on the substrate rest part PASS4 is taken by the transfer robot TR1 of the resist coating block 20 and put onto the substrate rest part PASS2, then being stored into the indexer block 10. The processed substrate W rested on the substrate rest part PASS2 is stored into a predetermined carrier C by the indexer robot IR. After that, the carrier C in which a predetermined number of processed substrates W are stored is unloaded to the outside of the apparatus, to complete a series of steps for photolithography process.

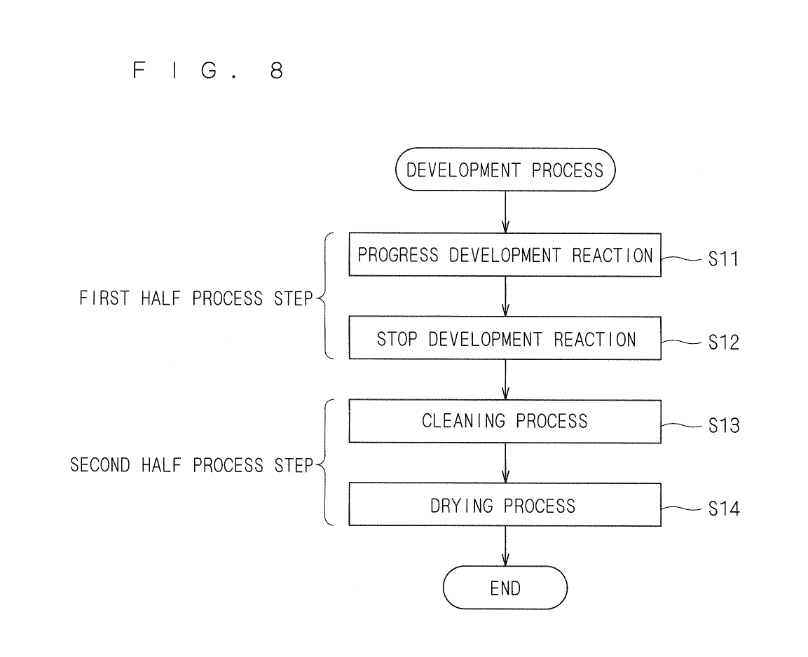

FIG. 8 is a flowchart showing a standard procedure of development process. As shown in FIG. 8, the general procedure of development process falls roughly into four steps, and specifically, a development reaction progressing step (Step S11) for progressing the development reaction by supplying a developer onto a substrate W, a development reaction stopping step (Step S 12) for stopping the development reaction by supplying de-ionized water onto the substrate W, a cleaning process step (Step S13) for cleaning the substrate W with de-ionized water and a drying process step (Step S14) for drying the cleaned substrate W are sequentially performed. Then, usually, all the steps are performed in the development part 41 of the development block 40.

Processing conditions (the respective amounts of solutions to be supplied, respective processing times for the process steps, the number of rotation for a substrate and the like) for the development process in the development part 41 are described in the recipe passed from the host computer 100 and depend on the type of resist film to be formed on a substrate W. Depending on the type of resist film, the processing time in the development part 41 may be long, and in such a case, the processing capability of the substrate processing apparatus 1 depends on the development process.

Then, in this embodiment, if the processing time in the development part 41 is long, the development process is split into two steps, and the first half of the process is performed by the development part 41 and the second half is performed by the cleaning part 31 of the cleaning block 30. Specifically, first, a processing time judgment part 101 of the main controller MC computes a processing time in the development part 41 from the recipe received from the host computer 100 and compares the processing time with a reference time determined in advance. Herein, the processing time in the development part 41 is a time period from when the development process on a substrate W starts to when the development process on the next substrate W stands ready to start in the development part 41, in consideration of the number of units. In other words, since a plurality of substrates W are processed in succession in the substrate processing apparatus 1, if a plurality of development units SD allowing concurrent processings are provided in the development part 41, the time interval until the process on the following substrate W stands ready to start becomes shorter depending on the number of units. If it takes 170 seconds for one development unit SD to perform a serial of steps, Steps S11 to S14, for the development process in accordance with the processing conditions described in the recipe, for example, the development part 41, which has five development units SD, takes a processing time of 170/5=34 seconds (a time interval until the development process on the following substrate W stands ready to start). This processing time is an apparent processing time per substrate in the development part 41 and is a direct indicator which indicates the processing capability of the development part 41.

Next, on the basis of the judgment result of the processing time judgment part 101, a mode selection part 102 of the main controller MC selects a mode for the development process. If the processing time in the development part 41 is longer than the reference time determined in advance, a “split processing mode” is selected, and if the processing time is shorter than the reference time, a “consecutive processing mode” is selected. As the reference time, for example, the longest one of the respective processing times of the processing parts other than the development part 41 may be determined, and is stored in a memory of the main controller MC in advance. Further, if the processing time in the development part 41 is equal to the reference time, either of the “split processing mode” and the “consecutive processing mode” may be selected.

When the mode selection part 102 selects the “consecutive processing mode”, since the processing time in the development part 41 is not long, all the steps, Steps S11 to S14, for the development process shown in FIG. 8 are performed in the development part 41. In this case, first, the transfer robot TR3 loads the substrate W into any one of the development units SD and puts it onto the spin chuck 403. The spin chuck 403 holds the substrate W in a substantially horizontal position by adsorption. Next, the developer is discharged like a curtain onto the upper surface of the substrate W from the slit nozzle 455 by opening the valve 457 while the slit nozzle 455 slidingly moves above the substrate W, to make a puddle of developer on the upper surface of the substrate W. By maintaining the condition where the puddle of developer is made on the upper surface of the substrate W for a predetermined time, the development reaction of the resist film after exposure progresses, to perform the development reaction progressing step of Step S11 in FIG. 8.

After the development for a predetermined time, de-ionized water is supplied onto the upper surface of the substrate W from the rinse nozzle 485 by opening the valve 492. As a result, the concentration of the puddle of developer decreases to stop the development reaction (Step S12). Further, as shown in Patent Documents 1 and 2, to stop the development reaction, a nozzle dedicated to supply of de-ionized water, like the slit nozzle 455, may be used. Subsequently, while the rinse nozzle 485 supplies de-ionized water, the chuck rotation driving mechanism 401 starts rotation of the rotation shaft 402 to rotate the substrate W held on the spin chuck 403. The developer on the upper surface of the substrate W and the product by dissolution of the resist film are rinsed off by the de-ionized water, to perform the cleaning process step of Step S 13.

After the cleaning process for a predetermined time, the supply of de-ionized water from the rinse nozzle 485 is stopped and a spin drying process is performed to shake the droplets off by increasing the number of rotation of the substrate W (Step S14). At the point of time when the spin drying process is finished, the development process in the development part 41 is completed. After that, the transfer robot TR3 unloads the substrate W after being subjected to the development process from the development unit SD and transfers it to any one of the heating units HP in the post-development thermal processing part 42. Through the thermal processing on the substrate W in the heating unit HP, the moisture in details of the pattern of the resist film is dried out. Then, the substrate W taken out from the heating unit HP by the transfer robot TR3 is transferred to any one of the cooling units CP in the post-development thermal processing part 42, where being cooled. After that, the substrate W is put onto the substrate rest part PASS6 by the transfer robot TR3 and then taken therefrom and put onto the substrate rest part PASS4 by the transfer robot TR2 of the cleaning block 30.

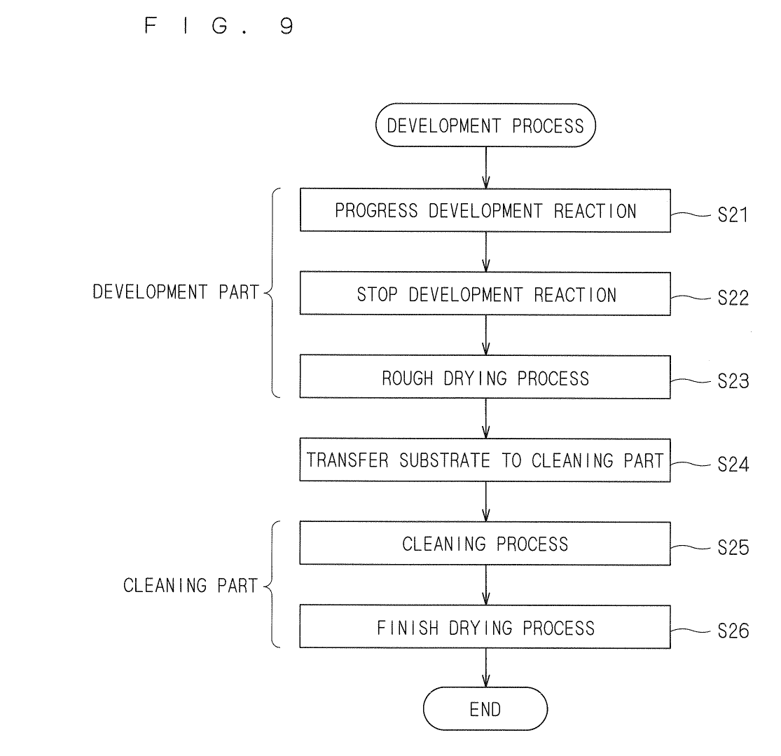

On the other hand, when the mode selection part 102 selects the “split processing mode”, since the processing time in the development part 41 is long, the processing including the first half process step of FIG. 8 is performed in the development part 41, and then the substrate W is transferred from the development block 40 to the cleaning block 30 and the processing including the second half process step is performed in the cleaning part 31. FIG. 9 is a flowchart showing a procedure of development process in a case where the split processing mode is selected.

In this case, first, the transfer robot TR3 loads the substrate W into any one of the development units SD and puts it onto the spin chuck 403. Then, the subsequent processings in a development reaction progressing step (Step S21) and a development reaction stopping step (Step S22) are the same as those in Steps S 1I and S 12 of FIG. 8, respectively. In the case of split processing mode, however, after the development reaction is stopped, a rough drying (spin drying) process is immediately performed, where the chuck rotation driving mechanism 401 rapidly rotates the substrate W to shake the developer off (Step S23).

After the rough drying process is finished, the process goes to Step S24, and the transfer robot TR3 unloads the substrate W from the development unit SD and puts it onto the substrate rest part PASS6. Then, the transfer robot TR2 of the cleaning block 30 receives the substrate W placed on the substrate rest part PASS6 and loads the received substrate W into any one of the cleaning units DIW in the cleaning part 31 and further puts it onto the spin chuck 303. Next, the chuck rotation driving mechanism 301 starts rotation of the rotation shaft 302, and with this rotation, the substrate W held on the spin chuck 303 is rotated. Then, by opening the valve 372, de-ionized water is supplied from the rinse nozzle 365 onto the upper surface of the substrate W. The upper surface of the substrate W is thereby cleaned by de-ionized water while being rotated (Step S25). Prior to the supply of de-ionized water, the dilute developer may be supplied onto the substrate W from the rinse nozzle 365 by opening the valve 374.

After the cleaning process for a predetermined time, the supply of de-ionized water from the rinse nozzle 365 is stopped and the drying nozzle 385 is moved to a position above the substrate W, replacing the rinse nozzle 365. Then, the chuck rotation driving mechanism 301 increases the number of rotation of the substrate W and opens the valve 392 to discharge the nitrogen gas onto the upper surface of the substrate W from the drying nozzle 385. A finish drying process is thereby performed on the substrate W with discharge of the nitrogen gas and rapid rotation (Step S26). At the point of time when the finish drying process for a predetermined time is finished, a series of steps for development process by the development part 41 and the cleaning part 31 are completed.

After that, the transfer robot TR2 unloads the substrate W after being subjected to the cleaning process from the cleaning unit DIW and transfers it to any one of the heating units HP in the post-development thermal processing parts 32 and 33. Through the thermal processing on the substrate W in the heating unit HP, the moisture in details of the pattern of the resist film is dried out. Then, the substrate W taken out from the heating unit HP by the transfer robot TR2 is transferred to any one of the cooling units CP in the post-development thermal processing parts 32 and 33, where being cooled. After that, the substrate W is put onto the substrate rest part PASS4 by the transfer robot TR2.

Thus, in this embodiment, if the processing time in the development part 41 is shorter than the reference time determined in advance, all the steps for the development process are performed in the development part 41 and if the processing time is longer than the reference time, the development process is split into two processes to be performed by the development part 41 and the cleaning part 31. In the case of split processing, the four process steps (Steps S11 to S14) for the development process shown in FIG. 8 are divided into the first half process step (Steps S11 and S12) and the second half process step (Steps S13 and S14), and the processing (Steps S21 to S23) including the first half process step is performed on the substrate W by the development part 41 and then the substrate W is transferred from the development part 41 to the cleaning part 31 and the processing (Steps S25 and S26) including the second half process step is performed on the substrate W by the cleaning part 31. Therefore, even if it takes a long time to perform the development process, splitting the development process prevents deterioration in processing capability of the substrate processing apparatus 1 on the whole.

If it takes 170 seconds for one development unit SD to perform a serial of steps, Steps S11 to S14, for the development process in accordance with the processing conditions described in the recipe, for example, the processing time in the development part 41 is 34 seconds as discussed above. If the processing time is shorter than the reference time, the “consecutive processing mode” is selected and all the four steps, Steps S11 to S14, for the development process are performed in the development part 41, and the processing capability is about 106 pieces per hour.

On the other hand, if the above-discussed processing time (34 seconds) in the development part 41 is longer than the reference time, the “split processing mode” is selected, and the processing including the first half process step is performed in the development part 41 and then the processing including the second half process step is performed in the cleaning part 31. In this case, it takes 100 seconds for one development unit SD of the development part 41 to perform the processing of Steps S21 to S23. Then, it takes 90 seconds for one cleaning unit DIW of the cleaning part 31 to perform the processing of Steps S25 and S26. Since the rough drying process (Step S23) which is not needed in the “consecutive processing mode” is executed in the “split processing mode”, the simple processing time per substrate W is 100+90=190 seconds, which is longer than the processing time in the “consecutive processing mode”.

Since five development units SD are provided in the development part 41 and five cleaning units DIW are provided in the cleaning part 31, however, the processing time of the development part 41 (a time interval until the development process on the following substrate W stands ready to start) is 20 seconds and the processing time in the cleaning part 31 is 18 seconds. Therefore, the processing capability of the development part 41 is 180 pieces per hour and the processing capability of the cleaning part 31 is 200 pieces per hour, and the processing capability of the substrate processing apparatus 1 on the whole obviously becomes higher than that in the “consecutive processing mode”.

Further, in the case where the development process is split, if the processing until the rough drying process is performed in the development part 41 and then the substrate W is passed to the cleaning part 31 as discussed above, since the developer is removed from the substrate W immediately after the development reaction is stopped, it is possible to surely prevent ingredients of the developer from soaking into the substrate W.

Furthermore, since the cleaning part 31 dedicated to the cleaning process which is the second half process step of the split development process is provided, not only the usual cleaning function with de-ionized water but also an additional cleaning function can be given to the cleaning units DIW. For example, though it is impossible to provide a mechanism for supplying hot de-ionized water to the development units SD of the development part 41 since the development reaction requires a strict control of temperature, a mechanism for supplying hot de-ionized water can be provided in the cleaning units DIW of the cleaning part 31 to supply hot de-ionized water onto the substrate W for the cleaning process. This allows variations in the cleaning process during the development process and it thereby becomes possible to more appropriately clean the substrates W.

In the substrate processing apparatus 1 of this embodiment, all the processing parts for performing a series of steps for the photolithography process are provided between the indexer block 10 and the interface block 50, and the development part 41 is arranged more closely to the interface block 50 than the cleaning part 31. In the substrate processing apparatus 1, the unexposed substrates W are transferred from the indexer block 10 towards the interface block 50 and the exposed substrates W are transferred from the interface block 50 towards the indexer block 10. Since the development part 41 for performing the first half process step is arranged more closely to the interface block 50 than the cleaning part 31 for performing the second half process step, even if the split processing mode is selected, the course of transfer is not disturbed and this makes it easy to control the transfer.

### 4. Variations

Thus, embodiments of the present invention have been discussed above, but numerous modifications and variations can be devised without departing from the scope of the invention. In splitting the development process, for example, process steps to be included in the first half process step and those to be included in the second half process step can be arbitrarily determined. Though the cleaning part 31 has to have a constitution to perform at least the second half process step, the cleaning part 31 may have the same constitution as that of the development part 41.

Further, the process to be split is not limited to the development process, and if the resist coating process performed in the resist coating part 21 takes a long time, for example, the resist coating process is split into the first half process step and the second half process step and an additional processing part dedicated to the second half process step may be provided in the substrate processing apparatus 1. Out of the resist coating process, the processing including the first half process step is performed in the resist coating part 21 and the processing including the second half process step is performed in the additional dedicated processing part. Also with this split processing, it is possible to prevent deterioration in processing capability of the substrate processing apparatus 1 on the whole.

In summary, if a specific process, out of the processes performed in a plurality of processing parts included in the substrate processing apparatus 1, takes a remarkably longer time (about twice as long as or more) than the other processes, the specific process is split into the first half process step and the second half process step and a processing part dedicated to the second half process step is provided in the substrate processing apparatus 1. The processing including the first half process step of the specific process is performed in a specific processing part for originally performing the specific process and the processing including the second half process step is performed in the processing part dedicated to the second half process step. With this manner, it is possible to prevent deterioration in processing capability even if the substrate processing includes a process which takes a longer time. The process to be split, however, has to be a process consisting of a plurality of process steps so as to be split.

Further, the construction of the substrate processing apparatus 1 of the present invention is not limited to that shown in FIGS. 2 to 4, and a processing block for forming an anti-reflection film under the resist film, for example, may be additionally provided.

While the invention has been shown and described in detail, the foregoing description is in all aspects illustrative and not restrictive. It is therefore understood that numerous modifications and variations can be devised without departing from the scope of the invention.

What is claimed is:

1. A substrate processing apparatus for performing a substrate processing while sequentially transferring a substrate to a plurality of processing parts, the substrate processing apparatus comprising:
a processing time judgment part for comparing a processing time required for a specific processing part out of the plurality of processing parts to perform a specific process comprising a plurality of process steps with a reference time determined in advance;
a mode selection part for selecting a split processing mode where the plurality of process steps are divided into at least a first portion process step and a second portion process step if the processing time in the specific processing part is longer than the reference time and selecting a consecutive processing mode if the processing time is shorter than the reference time;
a transfer part for transferring a substrate between a second portion processing part capable of performing the second portion process step and the specific processing part; and
a processing control part for controlling operations of the specific processing part, the second portion processing part and the transfer part,
the processing control part causing the specific processing part to perform all the plurality of process steps on a substrate when the consecutive processing mode is selected, and
the processing control part causing the specific processing part to perform a processing including the first portion process step on a substrate and then causing the transfer part to transfer the substrate from the specific processing part to the second portion processing part and causing the second portion processing part to perform a processing including the second portion process step on the substrate when the split processing mode is selected.

2. The substrate processing apparatus according to claim 1 wherein the specific process is a development process on a substrate after being subjected to an exposure process.

3. The substrate processing apparatus according to claim 2 wherein when the split processing mode is selected:
the specific processing part performs a development reaction progressing process for progressing a development reaction by supplying a developer onto a substrate, a development reaction stopping process for stopping the development reaction by supplying de-ionized water onto the substrate and a rough drying process; and
the second portion processing part performs a cleaning process and a finish drying process on the substrate.

4. The substrate processing apparatus according to claim 3 further comprising:
an indexer for loading an unprocessed substrate and unloading a processed substrate; and
an interface disposed adjacent to an exposure device, wherein the interface is configured to pass a substrate on which a resist film is formed to the exposure device and receive a substrate after being subjected to an exposure process from the exposure device,
wherein the plurality of processing parts are disposed between the indexer and the interface, and
the specific processing part is disposed closer to the interface than the second portion processing part.

5. The substrate processing apparatus according to claim 1 wherein the first portion process step comprises a first half process step and the second portion process step comprises a second half process step.

6. The substrate processing apparatus according to claim 1 wherein the plurality of process steps are divided into a first half process step and a second half process step if the processing time in the specific processing part is longer than the reference time.

7. A substrate processing apparatus for performing a development process on a substrate after being subjected to an exposure process, the substrate processing apparatus comprising:
a development part for performing a development reaction progressing process for progressing a development reaction by supplying a developer onto a substrate, a development reaction stopping process for stopping the development reaction by supplying de-ionized water onto the substrate and a rough drying process;
a cleaning part for performing a cleaning process and a finish drying process on the substrate after being subjected to the rough drying process; and
a transfer part for transferring the substrate after being subjected to the rough drying process from the development part to the cleaning part.

8. A substrate processing method for performing a substrate processing while sequentially transferring a substrate to a plurality of processing parts, the method comprising:
a) comparing a processing time required for a specific processing part out of the plurality of processing parts to perform a specific process including a plurality of process steps with a reference time determined in advance;
b) selecting a split processing mode where the plurality of process steps are divided into at least a first portion process step and a second portion process step if the processing time in the specific processing part is longer than the reference time and selecting a consecutive processing mode if the processing time is shorter than the reference time; and
c) performing all the plurality of process steps on a substrate in the specific processing part when the consecutive processing mode is selected, and performing a processing including the first portion process step on a substrate in the specific processing part and then transferring the substrate from the specific processing part to a second portion processing part capable of performing the second portion process step and performing a processing including the second portion process step on the substrate in the second portion processing part when the split processing mode is selected.

9. The substrate processing method according to claim 8 wherein the specific process is a development process on a substrate after being subjected to an exposure process.

10. The substrate processing method according to claim 9 wherein when the split processing mode is selected:
the first portion process step includes a development reaction progressing process for progressing a development reaction by supplying a developer onto a substrate, a development reaction stopping process for stopping the development reaction by supplying de-ionized water onto the substrate and a rough drying process, and
the second portion process step includes a cleaning process and a finish drying process on the substrate.

11. The substrate processing method according to claim 8 wherein the first portion comprises a first half and the second portion comprises a second half.

12. The substrate processing method according to claim 8 wherein the plurality of process steps are divided into a first half process step and a second half process step if the processing time in the specific processing part is longer than the reference time.
